(19) United States
(12) Patent Application Publication
(10) Pub. No.: US 2006/0146497 A1
(43) Pub. Date: Jul. 6, 2006

(54) Heat exchanger for memory modules

(75) Inventors: Paul Gauche, Portland, OR (US); Shawn McEuen, Portland, OR (US)

Correspondence Address: INTEL CORPORATION, P.O. BOX 5326, SANTA CLARA, CA, 95056-5326, US

(73) Assignee: Intel Corporation

(21) Appl. No.: 11/027,630

(22) Filed: Dec. 30, 2004

(51) Int. Cl. H05K 7/20

(52) U.S. Cl. 361/701

(57) ABSTRACT

A cooling system includes a heat spreader configured to wrap around a memory module inserted into a memory connector. The heat spreader is coupled to a heat exchanger and a fan.

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever.

### FIELD OF THE INVENTION

The present invention generally relates to cooling systems. More specifically, the present invention relates to cooling memory modules using a heat spreader and a local heat exchanger.

### BACKGROUND

Various cooling techniques have been developed to cool heat generated by components in computer systems. These techniques may include passive cooling and active cooling. Passive cooling may include the use of a heat pipe. Active cooling may include the use of a pump and a liquid transport.

Heat pipes and heat spreaders are commonly used in a cooling system to dissipate heat generated by integrated circuits (e.g., CPUs and chipsets) inside a computer system. Due to space limitations in today's compact computing systems, a traditional heat pipe and heat spreader may not work for every circuit inside a computer system, especially inside a laptop or portable computer systems. For example, when a small outline dual in-line memory module (SO-DIMM) is used in a laptop computer system, the space surrounding a SO-DIMM is so limited that a traditional heat pipe and heat spreader solutions may not fit. Thus, almost all laptop computers only rely on convective cooling for SO-DIMMs. As the capacity of SO-DIMMM increases, circuits in a SO-DIMM become denser, and more heat is generated, making convective cooling less effective.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIG. 1 is a block diagram illustrating an example of a computer system, in accordance with one embodiment.

FIGS. 2A and 2B illustrate an example of a top view and a side view of a memory connector and a memory module, in accordance with one embodiment.

FIG. 3 illustrates one example of a heat spreader, in accordance with one embodiment.

FIG. 4 illustrates an example of a heat spreader coupled to a heat exchanger, in accordance with one embodiment.

FIG. 5 illustrates an example of a heat spreader, heat exchanger, and a fan, in accordance with one embodiment.

FIG. 6 illustrates an example of a heat spreader coupled to a heat pipe, in accordance with one embodiment.

FIG. 7 illustrates another example of a heat spreader and a memory connector, in accordance with one embodiment.

FIG. 8 is a flow diagram illustrating a process of using a heat spreader to cool a memory module, in accordance with one embodiment.

### DETAILED DESCRIPTION

For one embodiment, a cooling system includes a heat spreader coupled to a memory connector. The heat spreader may be coupled to a heat exchanger. The heat spreader may be configured to wrap around a memory module when the memory module is inserted into the memory connector.

In the following description, for purposes of explanation, numerous specific details are set forth to provide a thorough understanding of the present invention. It will be evident, however, to one skilled in the art that the present invention may be practiced without these specific details. In other instances, well known structures, processes, and devices are shown in block diagram form or are referred to in a summary manner in order to provide an explanation without undue detail.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur.

Reference in the specification to “one embodiment” or “an embodiment” of the present invention means that a particular feature, structure or characteristic described in connection with the embodiment is included in at least one embodiment of the present invention. Thus, the appearances of the phrase “for one embodiment” or “in accordance with one embodiment” appearing in various places throughout the specification are not necessarily all referring to the same embodiment.

Computer System

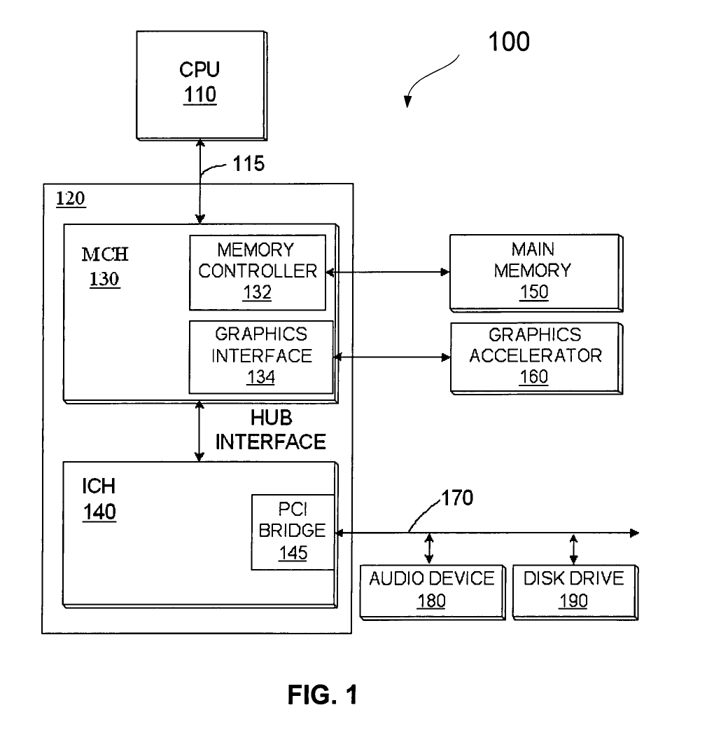

FIG. 1 is a block diagram illustrating an example of a computer system, in accordance with one embodiment. Computer system 100 includes a central processing unit (CPU) or processor 110 coupled to a bus 115. The processor 110 may be a processor available from the Intel Corporation of Santa Clara, Calif., although processors from other manufacturers may also be used. The computer system 100 may also include a chipset 120 coupled to the bus 115. The chipset 120 may include a memory control hub (MCH) 130 and an input/output control hub (ICH) 140.

The MCH 130 may include a memory controller 132 that is coupled to a main memory 150. The main memory 150 may store data and sequences of instructions that are executed by the processor 110 or any other device included in the system. The main memory 150 may include one or more of dynamic random access memory (DRAM), read-only memory (RAM), FLASH memory, etc. The MCH 130 may also include a graphics interface 134 coupled to a graphics accelerator 160. The graphics interface 134 may be coupled to the graphics accelerator 160 via an accelerated graphics port (AGP) that operates according to an AGP Specification Revision 2.0 interface developed by the Intel Corporation. A display (not shown) may be coupled to the graphics interface 134.

The MCH 130 may be coupled to the ICH 140 via a hub interface. The ICH 140 provides an interface to input/output (I/O) devices within the computer system. The ICH 140 may be coupled to a Peripheral Component Interconnect (PCI) bus. The ICH 140 may include a PCI bridge 145 that provides an interface to a PCI bus 170. The PCI Bridge 145 may provide a data path between the CPU 110 and peripheral devices such as, for example, an audio device 180 and a disk drive 190. Although not shown, other devices may also be coupled to the PCI bus 170 and the ICH 140.

Memory Module

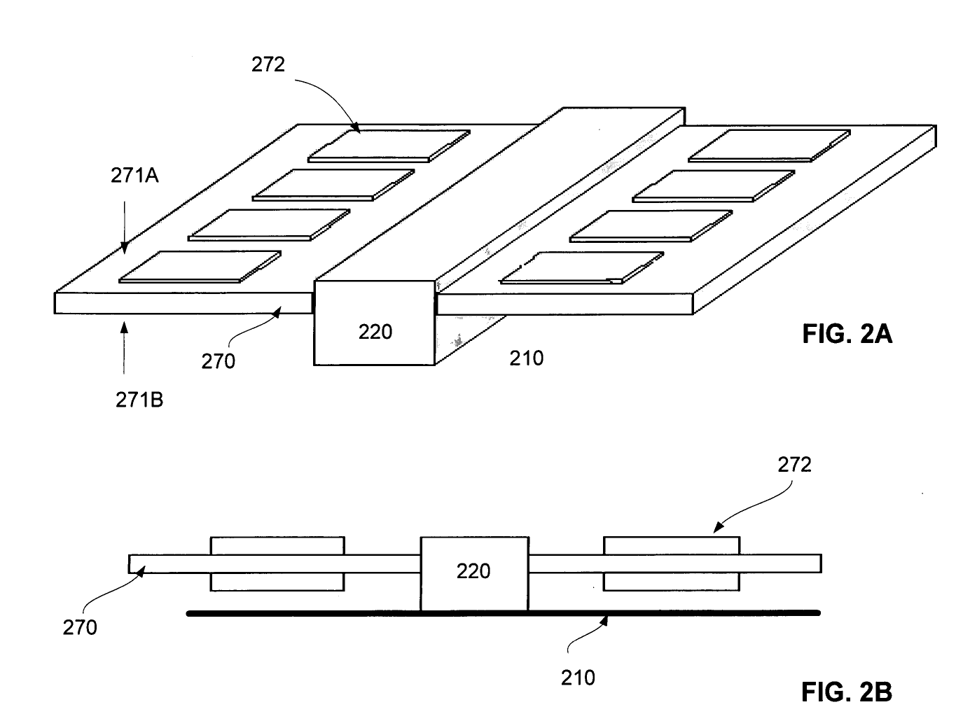

FIGS. 2A and 2B illustrate an example of a top view and a side view of a memory connector and a memory module, in accordance with one embodiment. The main memory 150 may include multiple memory modules such as, for example, memory module 270. The memory module 270 may include multiple components 272. The memory module 270 may be a small outline dual inline memory module (SO-DIMM) or any other type of memory module. The memory module 270 may be inserted into memory connector 220 which may connected to a system board 210 (also referred to as a mother board) of the computer system 100. The memory module 270 may have two planar surfaces 271A and 271B, with each surface having multiple components 272 and other circuits (not shown).

Referring to FIG. 2B, when the memory module 270 is inserted into the memory connector 220, the components on the side of the memory module 270 that faces the system board 210 may be warmer than those on the other side of the memory module 270. This may be because the space between the memory module 270 and the system board 210 is small. This may also be because that space is partially enclosed by the structure of the memory connector 220. The partially enclosed structure may result in poor air circulation for the components and any other circuits located on the system board side of the memory module 270.

Memory Module with Heat Spreader

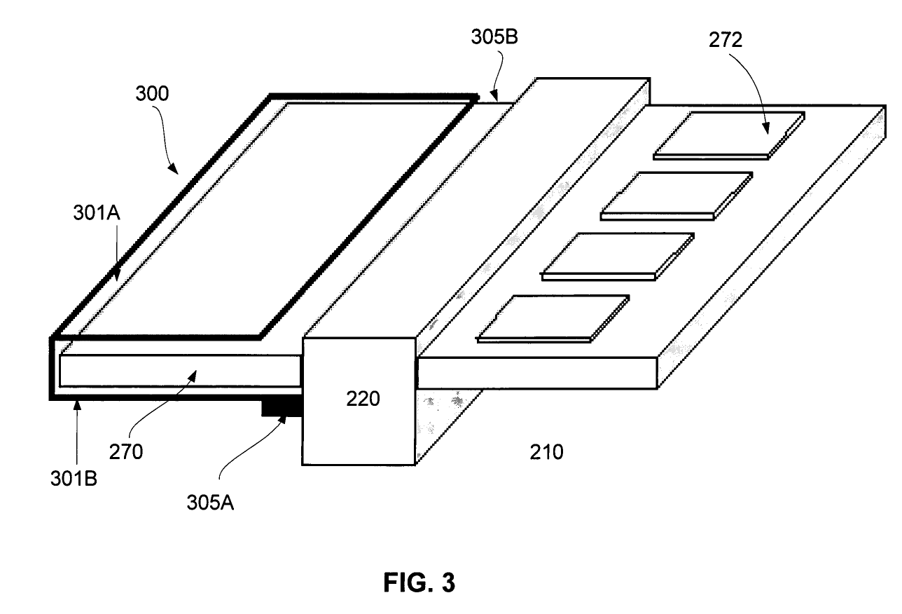

FIG. 3 illustrates one example of a heat spreader, in accordance with one embodiment. Heat spreader 300 may be coupled to memory connector 220 to help cool the components and any other circuits located on the system board side of the memory module 270. The memory connector 220 may include a pair of clips 305A and 305B (on opposite sides of the memory module 270) that may used to lock or to release the memory module 270 when the memory module 270 comes to rest in, clip into, or inserted into the memory connector 220. When the memory module 270 is inserted into the memory connector 220, the heat spreader 300 may help removing heat generated by the components 272 on the memory module 270.

For one embodiment, the heat spreader 300 is configured to wrap around the memory module 270. In this configuration, the heat spreader 300 includes two planar sections 301A and 301B. Each of the planar sections 301A and 301B of the heat spreader 300 is associated with each of the planar surfaces 271A and 271B of the memory module 270, respectively. The heat spreader 300 may be constructed of a thermally conductive material (e.g., copper, aluminum, metal alloy, any other suitable materials, or a mixture thereof) that has high heat transferability. The heat spreader 300 may include a layer of non-permanent thermal interface material (TIM) to provide substantially close thermal engagement between, for example, the planar sections 301A of the heat spreader 300 and the planar surface 271A of the memory module 270. The close thermal engagement may help improve heat transferring efficiency from the components 272 to the heat spreader 300. The non-permanent thermal interface material may be thermally conductive.

Typically, all of the components 272 may have the same height enabling them to be evenly in contact with the heat spreader 300. For one embodiment, when there is variation in the height of the components 272, coupling members (not shown) may be used. Each coupling member may include a spring member. The spring member may be constructed of a thermally conductive and flexible material so that it has both high heat transferability and good flexibility/recoverability. The shape of the spring member may allow the spring member to deform when pressure is exerted on the top and to release when the pressure is removed. The coupling members and spring members in the heat spreader 300 may help improving engagements between the heat spreader 300 and the components 272. They may also help make up for any potential height difference in the components 272. For one embodiment, ground pads (not shown) may be used to provide some cushion as well as insulation between the heat spreader 300 and the system board 210. The ground pads may help preventing the heat spreader 300 from damaging or disturbing the system board 210 or its components.

Heat Spreader with Heat Exchanger

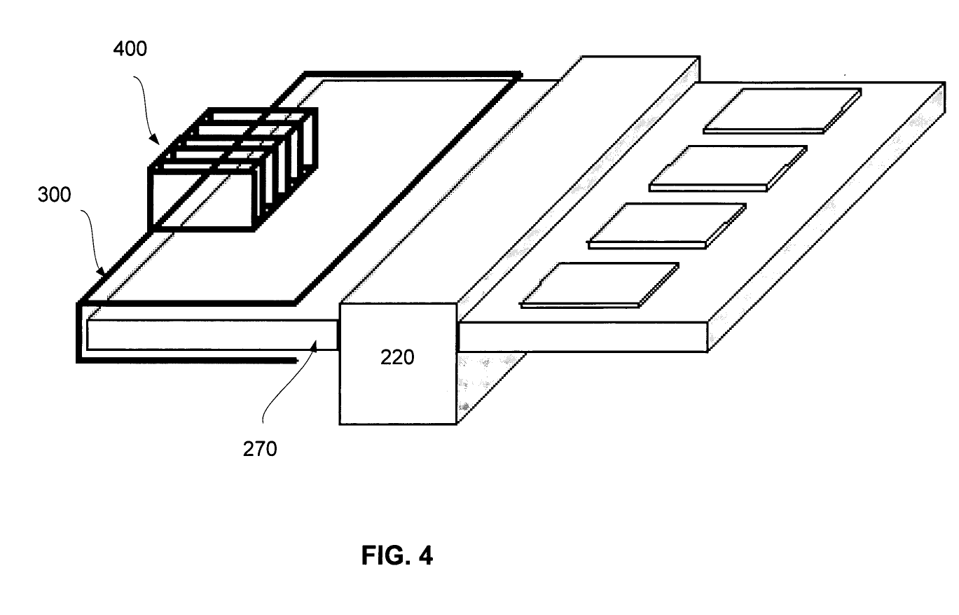

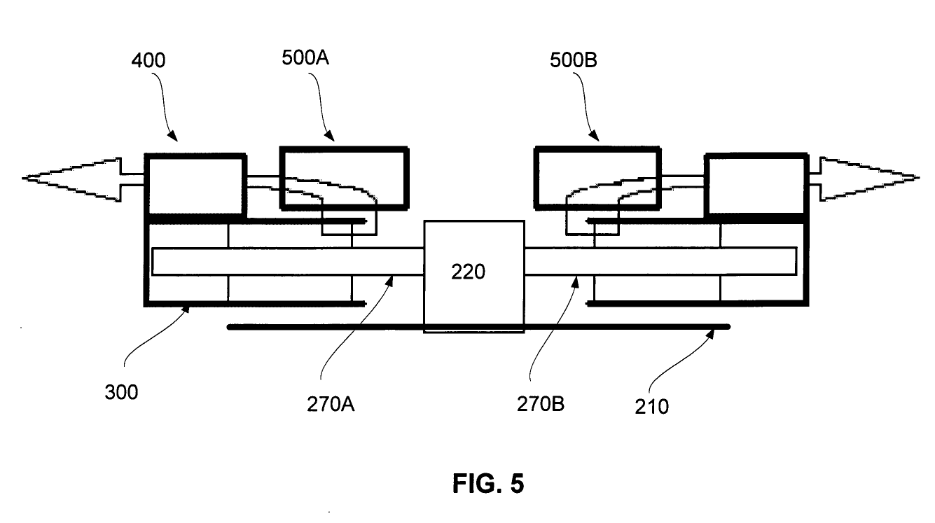

FIG. 4 illustrates an example of a heat spreader coupled to a heat exchanger, in accordance with one embodiment. Heat spreader 300 may be coupled to a local heat exchanger 400 to provide better cooling. The heat exchanger 400 is considered local because it is directly attached to the heat exchanger 300. For one embodiment, the heat exchanger 400 may be attached to the planar section 301A that faces away from the system board 210. For one embodiment, the heat exchanger 400 is coupled to a fan 500A, as illustrated in FIG. 5. The fan 500A may direct cool air flow toward the heat exchanger 300. FIG. 5 also illustrates one embodiment where the memory connector 220 may be coupled to two memory modules 270A and 270B, each coupling to a different set of heat spreader, heat exchanger, and fan. In this configuration, each of the fans 500A and 500B is positioned to direct air flow toward its corresponding heat exchanger and away from the other heat exchanger (as shown by the corresponding arrows).

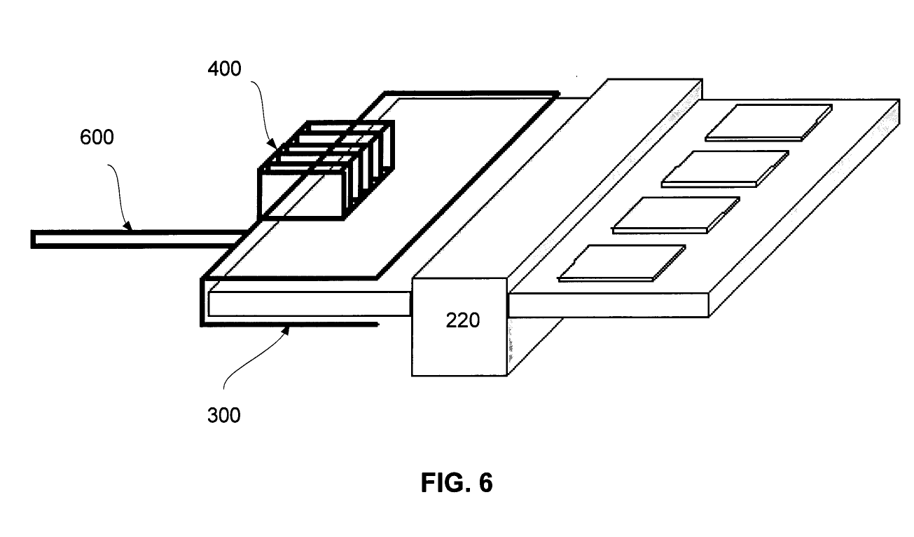

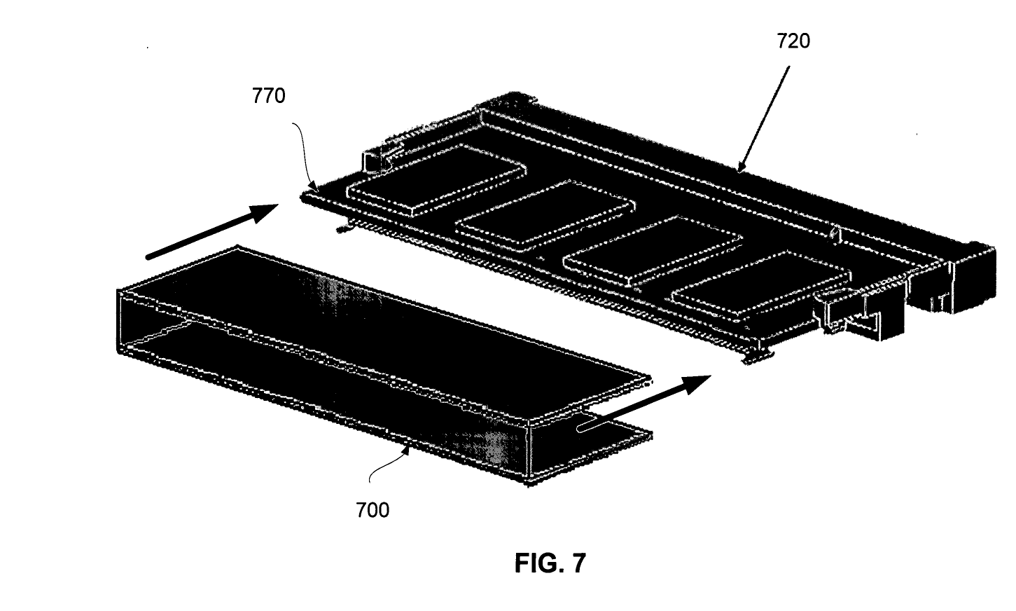

For one embodiment, the heat spreader 300 may be coupled to a heat pipe. This is illustrated in one example as heat pipe 600 in FIG. 6. The heat pipe 600 may be coupled to a remote heat exchanger (not shown). The remote heat exchanger may then dissipate the heat into ambient air inside a computer system or directly into outside of the computer system. FIG. 7 illustrates another example of a heat spreader 700 and a memory connector 720. In this example, memory module 770 is inserted into the memory connector 720. The heat spreader 700 may be coupled to the memory connector 720 by moving it in the direction shown by the arrows. The heat spreader 700 may then be attached to the memory connector 720 using clips as described above.

Process

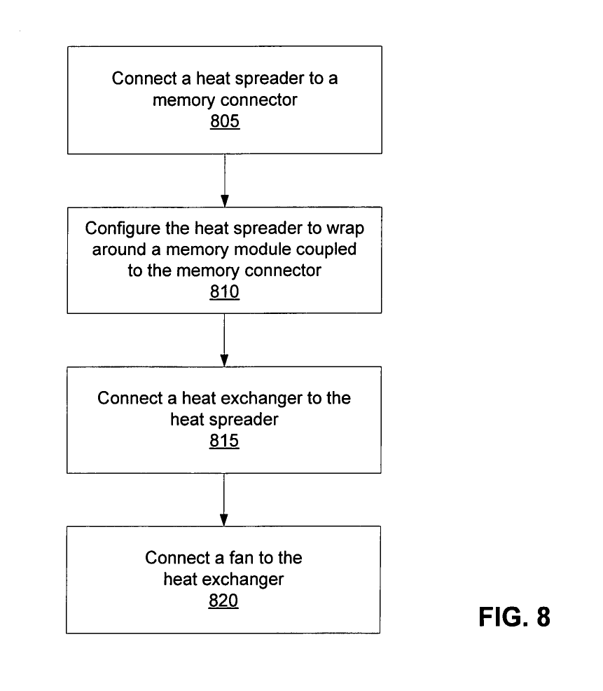

FIG. 8 is a flow diagram illustrating a process of using a heat spreader to cool a memory module, in accordance with one embodiment. At block 805, a heat spreader is connected to a memory connector. A memory module may have been inserted into the memory connector. The heat spreader may be connected to the memory connector using clips. The heat spreader may be formed in a shape that enables it to wrap around a memory module, as shown in block 810. This shape may generally be a “U” shape. At block 815, a heat exchanger is connected to the heat spreader. At block 820, a fan is connected to the heat exchanger. It may be noted that the flow chart described herein do not necessarily imply a fixed order to the actions, and embodiments may be performed in any order that is practicable.

In the preceding description, various aspects of the present disclosure have been described. For purposes of explanation, specific numbers, systems and configurations were set forth in order to provide a thorough understanding of the present disclosure. However, it is apparent to one skilled in the art having the benefit of this disclosure that the present disclosure may be practiced without the specific details. In other instances, well-known features, components, or modules were omitted, simplified, combined, or split in order not to obscure the present disclosure.

While this disclosure has been described with reference to illustrative embodiments, this description is not intended to be construed in a limiting sense. Various modifications of the illustrative embodiments, as well as other embodiments of the disclosure, which are apparent to persons skilled in the art to which the disclosure pertains are deemed to lie within the spirit and scope of the disclosure.

What is claimed is:

1. An apparatus, comprising:
a memory module connector to be coupled to a system board;
a heat spreader coupled to the memory module connector, wherein when a memory module is inserted into the memory module connector, a first section of the heat spreader is positioned along a first surface of the memory module; and
a heat exchanger directly coupled to the first section of the heat spreader.

2. The apparatus of claim 1, wherein a second section of the heat spreader is positioned along a second surface of the memory module.

3. The apparatus of claim 3, wherein the second section of the heat spreader is further positioned between the second surface of the memory module and the system board.

4. The apparatus of claim 3, further comprising:
a heat pipe coupled to the heat spreader.

5. The apparatus of claim 3, wherein the heat spreader is formed to enable partially wrapping around the memory module with the first section of the heat spreader corresponding to the first surface of the memory module and the second section of the heat spreader corresponding to the second surface of the memory module.

6. The apparatus of claim 5, wherein the heat spreader is formed generally in a “U” shape.

7. The apparatus of claim 1, further comprising:
a fan coupled to the heat exchanger.

8. A system, comprising:
a system board;
a memory connector coupled to the system board;
a memory module coupled to the memory connector, the memory module having a first planar surface and a second planar surface;
a heat spreader coupled to the memory connector, the heat spreader includes a first section positioned along the first planar surface of the memory module; and
a heat exchanger coupled to the first section of the heat spreader.

9. The system of claim 8, wherein the heat spreader includes a second section positioned along the second planar surface of the memory module.

10. The system of claim 9, wherein the heat spreader is coupled to a heat pipe.

11. The system of claim 9, wherein the heat spreader is coupled to a fan.

12. The system of claim 8, wherein the heat exchanger is directly coupled to the first section of the heat spreader.

13. The system of claim 8, wherein the memory module is a small outline dual in-line memory module (SO-DIMM).

14. A method, comprising:
attaching a heat spreader to a memory connector to enable cooling at least components on a memory module coupled to the memory connector, wherein the heat spreader is configured to generally cover surfaces of the memory module; and
attaching a heat exchanger to the heat spreader.

15. The method of claim 14, further comprising:
attaching a fan to the heat exchanger;

16. The method of claim 15, further comprising:
attaching a heat pipe to the heat spreader.

17. The method of claim 14, wherein the heat exchanger is attached directly to the heat spreader.

18. A heat spreader, comprising:
a first planar section to cool circuits on a first side of an electronic device;
a second planar section coupled to the first planar section and is to cool circuits on a second side of the electronic device; and
a heat exchanger directly coupled to the first planar section.

19. The heat spreader of claim 18, further comprising:
a fan coupled to the heat exchanger.

20. The heat spreader of claim 18, further comprising a heat pipe coupled to the first or to the second planar section.
